(19) United States
(12) Patent Application Publication
(10) Pub. No.: US 2024/0413288 A1
(43) Pub. Date: Dec. 12, 2024

(54) DISPLAY BASE PLATE AND PREPARATION METHOD THEREOF AND DISPLAY APPARATUS

(71) Applicant: BOE Technology Group Co., Ltd., Beijing (CN)

(72) Inventors: Can Zhang, Beijing (CN); Xinxin Zhao, Beijing (CN); Ning Cong, Beijing (CN); Minghua Xuan, Beijing (CN); Xiaochuan Chen, Beijing (CN)

(73) Assignee: BOE Technology Group Co., Ltd., Beijing (CN)

(21) Appl. No.: 18/696,006

(22) PCT Filed: Jun. 13, 2023
(86) PCT No.: PCT/CN2023/100004

§ 371 Date: Mar. 27, 2024

(30) Foreign Application Priority Data
Jun. 15, 2022 (CN) 202210674889.6

(51) Int. Cl. H01L 33/62; H01L 25/16; H01L 27/15; H01L 33/06; H01L 33/32; H01L 33/38; H01L 33/42

(52) U.S. Cl. CPC H01L 33/62; H01L 25/167; H01L 27/156; H01L 33/06; H01L 33/32; H01L 33/382; H01L 33/42

(57) ABSTRACT

Provided are a display base plate and a preparation method thereof and a display apparatus, belonging to the technical field of display devices. The display base plate comprises a substrate, and a light-emitting diode and a driving circuit which are patterned and arranged on one side of the substrate, and the light-emitting diode comprises a first semiconductor layer, a light-emitting layer and a second semiconductor layer which are stacked; and the driving circuit is respectively connected with the first semiconductor layer and the second semiconductor layer, and is used for driving the light-emitting diode to emit light. By the display base plate and the preparation method thereof and the display apparatus provided by the embodiment of the application, the difficulty of integrating the driving circuit and the light-emitting diode in the display base plate can be reduced, so that a preparation process of the display base plate is simpler.

### CROSS-REFERENCE TO RELATED APPLICATION

The present application claims the priority of the Chinese patent application filed on Jun. 15, 2022 before the CNIPA, China National Intellectual Property Administration with the application number of 202210674889.6 and the title of “DISPLAY BASE PLATE AND PREPARATION METHOD THEREOF AND DISPLAY APPARATUS”, which is incorporated herein in its entirety by reference.

### TECHNICAL FIELD

The embodiment of the present application relates to the technical field of display devices, and more particularly, to a display base plate and a preparation method thereof and a display apparatus.

### BACKGROUND

A Silicon-based light-emitting diode (LED) microdisplay technology is compatible with current semiconductor process, and is suitable for mass production. Compared with liquid crystal silicon (LCOS) and digital light processing (DLP) microdisplay technologies, the LED microdisplay technology does not need backlight, thus achieving a relatively light and thin entirety, a simple design for an optical system and a fast response speed. Compared with an organic light-emitting diode (OLED) microdisplay technology, the LED microdisplay technology adopts a semiconductor and a metal material completely, thus achieving high brightness, high temperature resistance, long service life, and the like.

At present, silicon-based LED microdisplay devices are all realized by flip-chip interconnection of a silicon-based active driving back plate and a bright monochrome LED array through dielectric metal, which is usually called a bonding technology.

### SUMMARY

In a first aspect, an embodiment of the present application provides a display base plate, which includes:
a substrate, wherein a light-emitting diode and a driving circuit are formed on one side of the substrate;
the light-emitting diode, including a first semiconductor layer, a light-emitting layer and a second semiconductor layer which are stacked; and
the driving circuit, respectively connected with the first semiconductor layer and the second semiconductor layer, and used for driving the light-emitting diode to emit light.

Alternatively, the first semiconductor layer is located between the substrate and the light-emitting layer, the first semiconductor layer comprises a first region, an orthographic projection of the first region and an orthographic projection of the light-emitting layer on the substrate are not overlapped, and the orthographic projection of the first region and an orthographic projection of the second semiconductor layer on the substrate are not overlapped.

Alternatively, the driving circuit includes a first metal layer, an insulating layer and a second metal layer which are stacked, the first metal layer is arranged close to the substrate, the first metal layer includes a first adapter portion, and the second metal layer includes a second adapter portion;
wherein, an orthogonal projection of the first adapter portion and the orthogonal projection of the first region on the substrate are overlapped and lapped with each other, and an orthogonal projection of the second adapter portion and the orthogonal projection of the second semiconductor layer on the substrate are overlapped and lapped with each other.

Alternatively, a passivation layer is also disposed on one side of the light-emitting diode away from the substrate, and the first metal layer is located on one side of the passivation layer away from the substrate;
wherein, the first adapter portion and the first region are lapped through a first via hole disposed in the passivation layer, and the second adapter portion and the second semiconductor layer are lapped through a second via bole disposed in the passivation layer.

Alternatively, the light-emitting diode further includes:
a first electrode located on a surface of one side of the first region away from the substrate; and
a second electrode located on a surface of one side of the second semiconductor layer away from the substrate.

Alternatively, the first electrode and the second electrode are made of a transparent conductive material.

Alternatively, the first semiconductor layer is made of N-GaN, and the second semiconductor layer is made of P-GaN.

Alternatively, the light-emitting layer is made of a multi-quantum well material.

Alternatively, a thickness of the first semiconductor layer is greater than that of the second semiconductor layer.

Alternatively, the thickness of the first semiconductor layer is greater than or equal to 2 μm and less than or equal to 3 μm; and
the thickness of the second semiconductor layer is greater than or equal to 0.5 μm and less than or equal to 1 μm.

Alternatively, a thickness of the light-emitting layer is greater than or equal to 0.3 μm and less than or equal to 0.7 μm.

Alternatively, the substrate is a silicon-based substrate.

Alternatively, the display base plate includes a plurality of pixels arranged in an array. and each pixel includes at least one light-emitting diode and the driving circuit connected with each light-emitting diode.

The second aspect of the present application discloses a display apparatus, comprising the display base plate according to the first aspect.

The third aspect of the present application discloses a preparation method of a display base plate, comprising the following steps of:
providing a substrate;
forming a light-emitting diode on one side of the substrate, wherein the light-emitting diode includes a first semiconductor layer, a light-emitting layer and a second semiconductor layer which are stacked; and
forming a driving circuit on the side of the substrate, wherein the driving circuit is respectively connected with the first semiconductor layer and the second semiconductor layer, and is used for driving the light-emitting diode to emit light.

### BRIEF DESCRIPTION OF THE DRAWINGS

To clearer illustrate the technical solutions implemented in the embodiment of the application, a brief introduction to the figures required in the description of the embodiment of the application will be provided below. Obviously, the figures described below are merely some embodiments of this application. A skilled person in the art can obtain other figures based on these figures without exerting creative labor.

FIG. 1 is a schematic diagram of a planar structure of a display base plate provided by an embodiment of the present application;

FIG. 2 is a schematic diagram of a sectional structure along a sectional line C-D in FIG. 1;

FIG. 3 is a step flow chart of a preparation method of the display base plate provided by the embodiment of the present application;

FIG. 4 is a schematic structural diagram of completing preparation of a substrate in the preparation method of the display base plate provided by the embodiment of the present application;

FIG. 5 is a schematic structural diagram of completing preparation of a first semiconductor layer, a light-emitting layer and a second semiconductor layer in the preparation method of the display base plate provided by the embodiment of the present application;

FIG. 6 is a schematic structural diagram of completing preparation of a light-emitting diode in the preparation method of the display base plate provided by the embodiment of the present application;

FIG. 7 is a schematic structural diagram of completing preparation of a first electrode and a second electrode in the preparation method of the display base plate provided by the embodiment of the present application;

FIG. 8 is a schematic structural diagram of completing preparation of a passivation layer in the preparation method of the display base plate provided by the embodiment of the present application;

FIG. 9 is a schematic structural diagram of completing etching of the passivation layer in the preparation method of the display base plate provided by the embodiment of the present application; and

FIG. 10 is a schematic structural diagram of completing preparation of a driving circuit in the preparation method of the display base plate provided by the embodiment of the present application.

### DESCRIPTION OF REFERENCE NUMERALS

10 substrate; 20 light-emitting diode; 201 first semiconductor layer; 2011 first region; 202 light-emitting layer; 203 second semiconductor layer; 204 passivation layer; 205 first electrode; 206 second electrode; 30 driving circuit; 301 first metal layer; 3011 first adapter portion; 302 insulating layer; 303 second metal layer; 3031 second adapter portion; A light-emitting region; and B non-light-emitting region.

### DETAILED DESCRIPTION

A clear and comprehensive description of the technical solutions in the embodiments of the application embodiment will be provided below in connection with the figures. Clearly, the described embodiments are part of the embodiments of this application, not all of them. Based on the embodiments in the application, all other embodiments obtained by a skilled person in the art without exerting creative labor are within the scope protected by the application.

In the related art, a driving circuit and a light-emitting diode in a display base plate are usually formed on different substrates, so that, when the display base plate is prepared, after the light-emitting diode and the driving circuit are respectively formed, the light-emitting diode and the driving circuit need to be connected by a bonding technology to realize the power supply and control of the light-emitting diode. However, in order to deal with high PPI (Pixels Per Inch) silicon-based microdisplay, the requirement of alignment accuracy between the driving circuit and the light-emitting diode is as high as 0.5 μm, which is a big bottleneck in the field of alignment equipment at present. That is to say, the disadvantage of the bonding technology is that the alignment accuracy of bonding equipment is very high, which leads to a complicated preparation process of the display base plate.

In view of this, an embodiment of the present application provides a display base plate and a preparation method thereof and a display apparatus to reduce the difficulty of integrating a driving circuit and a light-emitting diode in the display base plate, so that a preparation process of the display base plate is simpler.

Specifically, the embodiment of the present application provides the display base plate and the preparation method thereof and the display apparatus, wherein the light-emitting diode is formed in a light-emitting region of a substrate, the driving circuit is formed in a non-light-emitting region of the substrate, and meanwhile, the light-emitting diode includes a first semiconductor layer, a light-emitting layer and a second semiconductor layer which are stacked, so that the driving circuit is respectively connected with the first semiconductor layer and the second semiconductor layer to realize light emission of the light-emitting diode; and in this way, the driving circuit and the light-emitting diode are formed on the same substrate at the same time, and the integration of the driving circuit and the light-emitting diode does not need to be completed by the bonding technology, thus reducing the difficulty of integrating the driving circuit and the light-emitting diode in the display base plate, so that a preparation process of the display base plate is simpler.

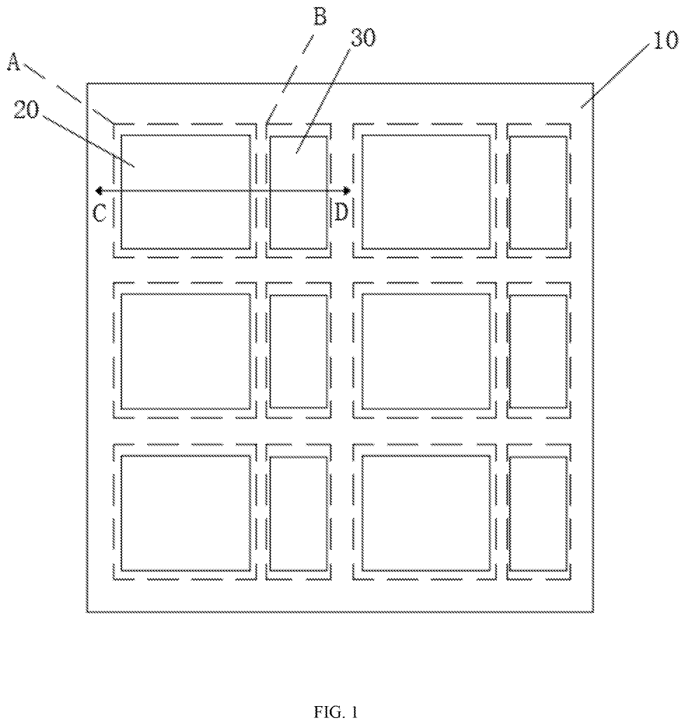

With reference to FIG. 1, an embodiment of the present application discloses a display base plate, which includes a substrate 10, and a light-emitting diode 20 and a driving circuit 30 which are patterned and arranged on one side of the substrate 10.

Specifically, with reference to FIG. 1, in a preparation process of the display base plate, a light-emitting region A and a non-light-emitting region B are divided on the substrate 10. The light-emitting region A refers to a region for providing light in the display base plate, and the non-light-emitting region B refers to a region not providing light in the display base plate. The light provided by the light-emitting region A may include red light, blue light, green light, and the like.

The substrate 10 may be a silicon-based substrate. Specifically, the substrate 10 may be made of monocrystalline silicon or polycrystalline silicon.

The light-emitting diode 20 and the driving circuit 30 are formed on the same substrate 10, wherein the light-emitting diode 20 is formed in the light-emitting region A on the substrate 10, while the driving circuit 30 is formed in the non-light-emitting region B on the substrate 10, so that an influence of the driving circuit 30 on a light-emitting effect of the display base plate can be reduced.

With reference to FIG. 2, the light-emitting diode 20 includes a first semiconductor layer 201, a light-emitting layer 202 and a second semiconductor layer 203 which are sequentially stacked on the substrate 10. Specifically, the first semiconductor layer 201 and the second semiconductor layer 203 respectively serve as an anode and a cathode of the light-emitting diode 20. After the first semiconductor layer 201 and the second semiconductor layer 203 are respectively connected to the driving circuit 30, the driving circuit 30 may be used to make the light-emitting diode 20 emit light.

Meanwhile, with reference to FIG. 6, the first semiconductor layer 201 includes a first region 2011, and an orthographic projection of the first region 2011 on the substrate 10 is not overlapped with orthographic projections of the light-emitting layer 202 and the second semiconductor layer 203 on the substrate 10.

It should be noted that, when the display base plate is prepared, a preparation sequence of the light-emitting diode 20 and the driving circuit 30 is not fixed, that is, the light-emitting diode 20 may be formed on the substrate 10 first, and then the driving circuit 30 is formed; or the driving circuit 30 may be formed on the substrate 10 first, and then the light-emitting diode 20 is formed.

In this way, by forming the light-emitting diode 20 and the driving circuit 30 on the same substrate 10, a bonding process is not needed to realize the connection between the light-emitting diode 20 and the driving circuit 30 when the display base plate is prepared, thus avoiding the requirement for alignment accuracy of the light-emitting diode 20 and the driving circuit 30 in the preparation process, so that the preparation process of the display base plate is simpler.

Further, in the embodiment of the present application, the first semiconductor layer 201 is made of N-GaN, the second semiconductor layer 203 is made of P-GaN, and the light-emitting layer 202 is made of a multi-quantum well material.

Meanwhile, a thickness of the first semiconductor layer 201 is greater than that of the second semiconductor layer 203. In specific applications, the thickness of the first semiconductor layer 201 is greater than or equal to 2 μm and less than or equal to 3 μm; and illustratively, the thickness of the first semiconductor layer 201 may be 2 μm, 2.2 μm, 2.4 μm, 2.6 μm, 2.8 μm, 3 μm, and the like. The thickness of the second semiconductor layer 203 is greater than or equal to 0.5 μm and less than or equal to 1 μm; and illustratively, the thickness of the second semiconductor layer 203 may be 0.5 μm, 0.6 μm, 0.7 μm, 0.8 μm, 0.9 μm, 1 μm, and the like. The thickness of the light-emitting layer 202 is greater than or equal to 0.3 μm and less than or equal to 0.7 μm; and illustratively, the thickness of the light-emitting layer 202 may be 0.3 μm, 0.4 μm, 0.5 μm, 0.6 μm, 0.7 μm, and the like.

In an optional embodiment, the present application provides a display base plate, and with reference to FIG. 2, in the display base plate, the driving circuit 30 includes a first metal layer 301, an insulating layer 302 and a second metal layer 303 which are stacked.

Specifically, in the display base plate, the first metal layer 301 is arranged closer to the substrate 10, and the first metal layer 301 includes a first adapter portion 3011. An orthographic projection of the first adapter portion 3011 on the substrate 10 is overlapped with the orthographic projection of the first region 2011 of the first semiconductor layer 201 on the substrate 10, and the first adapter portion 3011 is lapped with the first region 2011 of the first semiconductor layer 201. Meanwhile, the second metal layer 303 includes a second adapter portion 3031, an orthographic projection of the second adapter portion 3031 on the substrate 10 is overlapped with the orthographic projection of the second semiconductor layer 203 on the substrate 10, and the second adapter portion 3031 is lapped with the second semiconductor layer 203.

That is, the first adapter portion 3011 is electrically connected with the first semiconductor layer 201, and the second adapter portion 3031 is electrically connected with the second semiconductor layer 203, thus realizing the electrical connection between the driving circuit 30 and the light-emitting diode 20, so that the driving circuit 30 may input a current to the light-emitting diode 20 through the first metal layer 301 and the second metal layer 303 to realize light emission of the light-emitting diode 20.

By the display base plate provided by the embodiment of the present application, the first adapter portion 3011 of the first metal layer 301 and the second adapter portion 3031 of the second metal layer 303 are used to realize the electrical connection between the driving circuit 30 and the light-emitting diode 20, so that the driving circuit 30 and the light-emitting diode 20 may be better formed on the same substrate 10, thus further making the preparation process of the display base plate simpler.

The driving circuit 30 in the display base plate may be a CMOS (Complementary Metal Oxide Semiconductor) circuit, so that the driving circuit 30 may be formed by a CMOS process, and illustratively, the driving circuit 30 may be formed by a P-well CMOS process, an N-well CMOS process and a double-well CMOS process.

FIG. 2 shows the driving circuit 30 formed by the N-well CMOS process in the embodiment of the present application. In the driving circuit 30, the driving circuit 30 further includes a deep N-well layer (not shown in the drawings) formed on the substrate 10, a medium-voltage-well layer (not shown in the drawings) arranged on the deep N-well layer, a lightly doped drain (not shown in the drawings) arranged on the medium-voltage-well layer, and a gate, a source and a drain (not shown in the drawings) arranged on the lightly doped drain. It should be noted that the driving circuit formed by the N-well CMOS process is an existing structure in the related art, which will not be repeated in the embodiment of the present application.

In an optional embodiment, the embodiment of the present application provides a display base plate, and with reference to FIG. 2, in the display base plate, a passivation layer 204 is also arranged on one side of the light-emitting diode 20 away from the substrate 10, and the first metal layer 301 is located on one side of the passivation layer 204 away from the substrate 10.

Specifically, in the preparation process of the display base plate, if the light-emitting diode 20 is formed first, and then the driving circuit 30 is formed, one passivation layer 204 needs to be formed on a surface of the light-emitting diode 20 after the light-emitting diode 20 is formed, and the passivation layer 204 may be used to protect the light-emitting diode 20, thus avoiding damage to the light-emitting diode 20 in a subsequent forming process of the driving circuit 30.

Meanwhile, because the passivation layer 204 is formed, when the first metal layer 301 is connected with the first semiconductor layer 201 and the second metal layer 303 is connected with the second semiconductor layer 203, the first adapter portion 3011 may be lapped with the first region 2011 of the first semiconductor layer 201 through a first via hole arranged in the passivation layer 204, and the second adapter portion 3031 may be lapped with the second semiconductor layer 203 through a second via hole arranged in the passivation layer 204.

The passivation layer 204 may be made of an organic material, such as resin; and may also be made of an inorganic material, such as SiO₂.

By the display base plate provided by the embodiment of the present application, the passivation layer 204 is used to protect the light-emitting diode 20, which avoids the damage to the light-emitting diode 20 caused in the preparation process of the display base plate, and realizes the formation of the light-emitting diode 20 and the driving circuit 30 on the same substrate 10 at the same time, so that the preparation process of the display base plate is simpler.

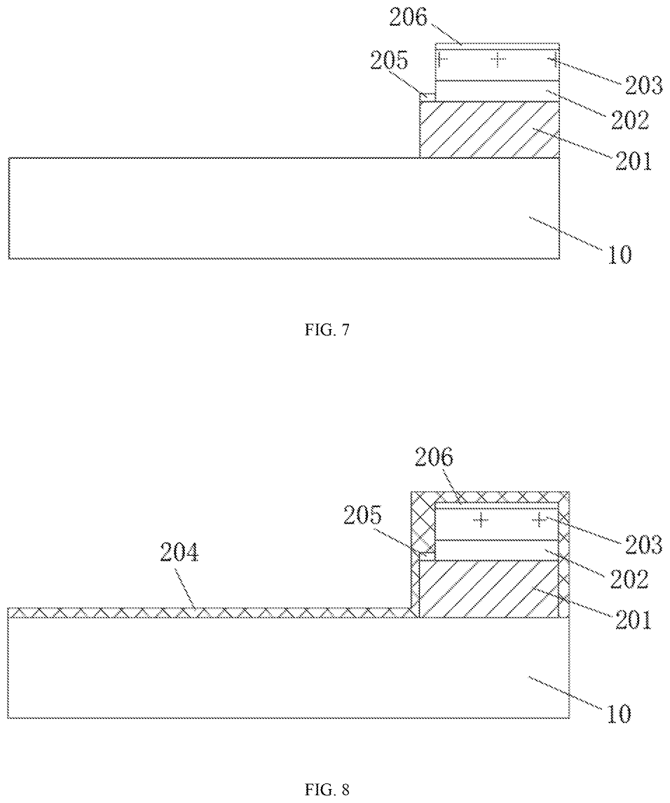

In an optional embodiment, the embodiment of the present application provides a display base plate, and with reference to FIG. 7, in the display base plate, the light-emitting diode 20 includes a first electrode 205 and a second electrode 206.

Specifically, the first electrode 205 is arranged on a surface of one side of the first region 2011 of the first semiconductor layer 201 away from the substrate 10, and the second electrode 206 is arranged on a surface of one side of the second semiconductor layer 203 away from the substrate 10. The first adapter portion 3011 of the first metal layer 301 is electrically connected with the first semiconductor layer 201 through the first electrode 205, and the second adapter portion 3031 of the second metal layer 303 is electrically connected with the second semiconductor layer 203 through the second electrode 206.

Meanwhile, in order to improve light-emitting efficiency of the light-emitting diode 20, the first electrode 205 and the second electrode 206 may be made of a transparent conductive material, such as indium tin oxide.

By the display base plate provided by the embodiment of the present application, the arrangement of the first electrode 205 and the second electrode 206 can reduce contact resistance between the first adapter portion 3011 and the first semiconductor layer 201 and contact resistance between the second adapter portion 3031 and the second semiconductor layer 203, thus improving the light-emitting efficiency, and the first electrode 205 and the second electrode 206 are both made of the transparent conductive material, thus further improving the light-emitting efficiency of the light-emitting diode 20.

In an optional embodiment, the embodiment of the present application provides a display base plate, the display base plate includes a plurality of pixels arranged in an array, and each pixel includes at least one light-emitting diode 20 and the driving circuit 30 connected with each light-emitting diode 20.

Based on the same inventive concept, the embodiment of the present application further provides a display apparatus, which includes the display base plate provided by any one of the above embodiments of the present application, wherein the display base plate may serve as backlight of the display apparatus or the display base plate of the display apparatus.

Specifically, the display apparatus may include an organic light-emitting diode (OLED) 20 display screen, a mobile device such as a mobile phone, a wearable device such as a watch, a virtual reality (VR) device, and the like, and those skilled in the art may make corresponding choices according to specific uses of the display device, which will not be repeated herein.

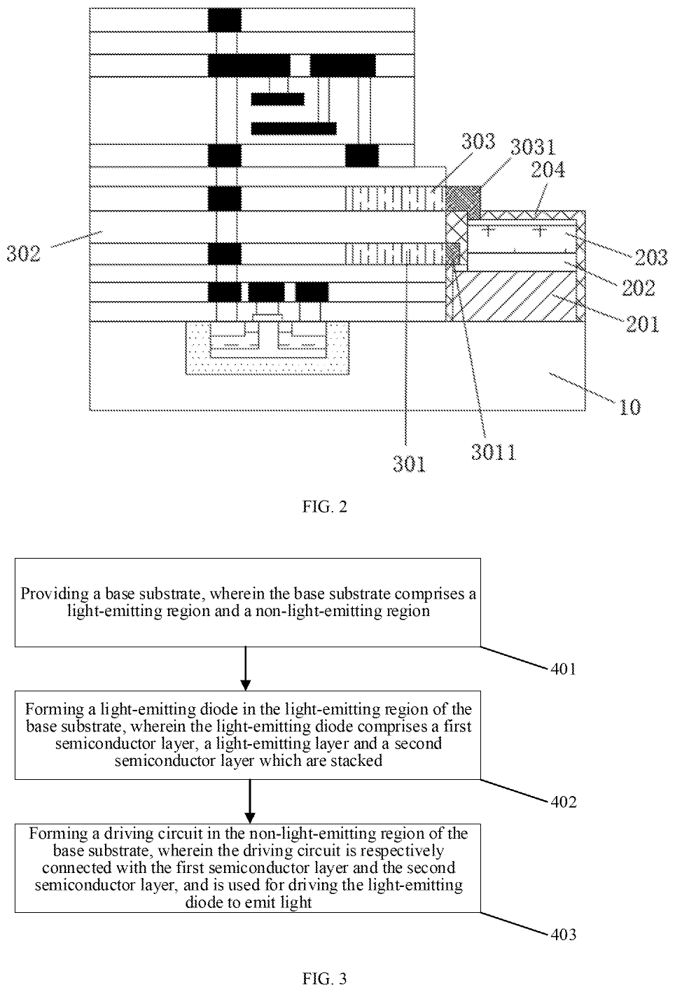

FIG. 3 shows a step flow chart of a preparation method of the display base plate. With reference to FIG. 3, the embodiment of the present application discloses a preparation method of the display base plate, and the preparation method includes the following steps.

In step 401, the substrate 10 is provided, wherein the substrate 10 includes the light-emitting region A and the non-light-emitting region B.

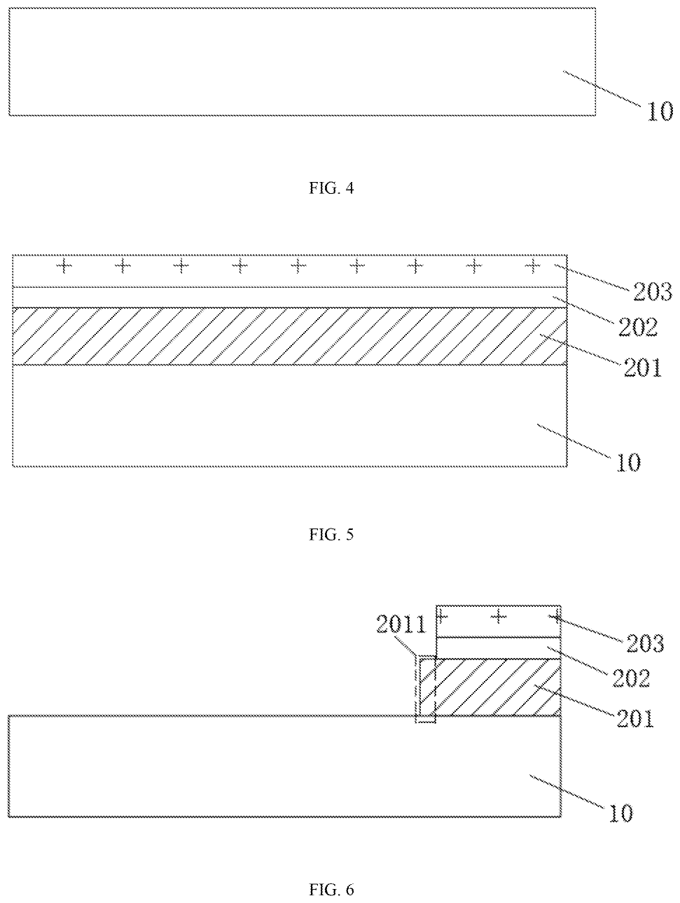

Specifically, the substrate 10 may be a silicon-based substrate, and the silicon-based substrate may include monocrystalline silicon or polycrystalline silicon. The light-emitting region A and the non-light-emitting region B may be divided on the substrate 10 before preparing the display base plate, but it should be noted that the light-emitting region A and the non-light-emitting region B are actually a virtual region, as shown in FIG. 4.

In step 402, the light-emitting diode 20 is formed in the light-emitting region A of the substrate 10, wherein the light-emitting diode 20 includes the first semiconductor layer 201, the light-emitting layer 202 and the second semiconductor layer 203 which are stacked.

Specifically, the first semiconductor layer 201, the light-emitting layer 202 and the second semiconductor layer 203 may be sequentially formed on the substrate 10 through a vapor phase epitaxy process, and meanwhile, the first semiconductor layer 201, the light-emitting layer 202 and the second semiconductor layer 203 are patterned through photoetching and etching processes to finally form the light-emitting diode 20. Moreover, the first semiconductor layer 201 includes the first region 2011, and the orthographic projection of the first region 2011 on the substrate 10 is not overlapped with the orthographic projections of the light-emitting layer 202 and the second semiconductor layer 203 on the substrate 10, as shown in FIG. 5 and FIG. 6.

The first semiconductor layer 201 is made of N-GaN, the second semiconductor layer 203 is made of P-GaN, and the light-emitting layer 202 is made of a multi-quantum well material. The thickness of the first semiconductor layer 201 may be greater than or equal to 2 μm and less than or equal to 3 μm; the thickness of the second semiconductor layer 203 may be 0.6 μm; and the thickness of the light-emitting layer 202 may be 0.5 μm.

In step 403, the driving circuit 30 is formed in the non-light-emitting region B of the substrate 10, wherein the driving circuit 30 is respectively connected with the first semiconductor layer 201 and the second semiconductor layer 203, and is used for driving the light-emitting diode 20 to emit light.

Specifically, the driving circuit 30 includes the first metal layer 301, the insulating layer 302 and the second metal layer 303 which are stacked, wherein the first metal layer 301 includes the first adapter portion 3011, and the second metal layer 303 includes the second adapter portion 3031. The orthographic projection of the first adapter portion 3011 on the substrate 10 is overlapped with the orthographic projection of the first region 2011 on the substrate 10, and the first adapter portion 3011 and the first region 2011 are lapped with each other; and the orthographic projection of the second adapter portion 3031 on the substrate 10 is overlapped with the orthographic projection of the second semiconductor layer 203 on the substrate 10, and the second adapter portion 3031 and the second semiconductor layer 203 are lapped with each other, as shown in FIG. 10.

It should be noted that, in the preparation method, a sequence of the step 402 and the step 403 is not fixed, that is, the step 402 may be completed first and then the step 403 is completed; or the step 403 may be completed first and then the step 402 is completed. In the embodiment of the present application, a preparation sequence of the light-emitting diode 20 and the driving circuit 30 is not limited.

In addition, in the preparation sequence that the step 402 is completed first and then the step 403 is completed, in order to avoid the light-emitting diode 20 from being damaged, the preparation method further includes the following step.

In step 404, the passivation layer 204 is formed on one side of the light-emitting diode 20 away from the substrate 10.

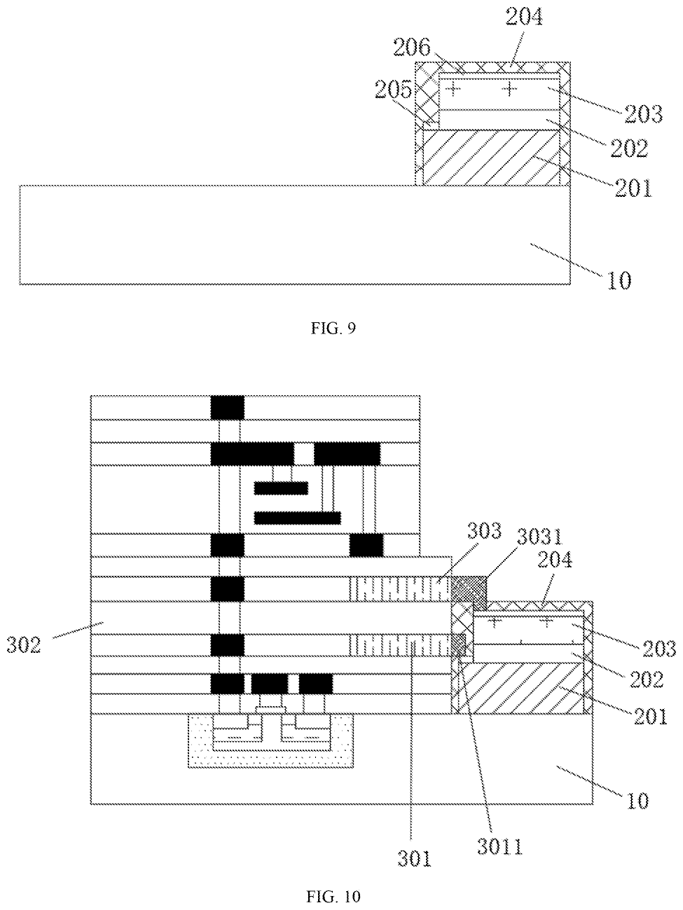

Specifically, the passivation layer 204 may be made of an organic material, such as resin; and may also be made of an inorganic material, such as SiO₂, as shown in FIG. 8 and FIG. 9.

Further, in order to reduce contact resistance between the light-emitting diode 20 and the driving circuit 30, the preparation method further includes the following step.

In step 405, the first electrode 205 is formed on the surface of one side of the first region 2011 away from the substrate 10, and the second electrode 206 is formed on the surface of one side of the second semiconductor layer 203 away from the substrate 10.

Specifically, the first electrode 205 and the second electrode 206 may be made of a transparent conductive material, such as indium tin oxide, so as to improve the light-emitting efficiency of the light-emitting diode 20, as shown in FIG. 7.

According to the display base plate and the preparation method thereof and the display apparatus provided by the embodiment of the present application, the light-emitting diode is formed in the light-emitting region of the substrate, the driving circuit is formed in the non-light-emitting region of the substrate, and meanwhile, the light-emitting diode includes the first semiconductor layer, the light-emitting layer and the second semiconductor layer which are stacked, so that the driving circuit is respectively connected with the first semiconductor layer and the second semiconductor layer to realize light emission of the light-emitting diode; and in this way, the driving circuit and the light-emitting diode are formed on the same substrate at the same time, and the integration of the driving circuit and the light-emitting diode does not need to be completed by the bonding technology, thus reducing the difficulty of integrating the driving circuit and the light-emitting diode in the display base plate, so that the preparation process of the display base plate is simpler.

It should be noted that each embodiment in the specification is described in a progressive manner, and each embodiment focuses on the differences from other embodiments, and the same or similar parts between each embodiment can refer to each other.

It should also be noted that, in this document, the terms “center”, “up”, “down”, “left”, “right”, “vertical”, “horizontal”, “inner”, “outer”, etc., indicate orientations or positional relationships based on those shown in the drawings and are intended solely for convenience and simplification of the present application, and do not indicate or imply that the device or element referred to must have a particular orientation, be constructed and operated in a particular orientation, and therefore cannot be construed as limiting the present application. In addition, relational terms such as “first” and “second” are used solely to distinguish one entity or operation from another, and do not necessarily require or imply any such actual relationship or sequence between those entities or operations, nor can they be construed as indicating or implying relative importance. Further, the term “including”, “including” or any other variation thereof is intended to cover non-exclusive inclusion so that a process, process, article or terminal device comprising a series of elements includes not only those elements but also other elements that are not expressly listed, or that are inherent to such process, process, article or terminal device. In the absence of further restrictions, an element qualified by the statement “including a . . . ” does not preclude the existence of other identical elements in the process, method, article or terminal equipment that includes the element.

The above technical solutions provided in the present application are described in detail, and the principles and embodiments of the present application are elaborated in this article by applying specific examples, and the descriptions of the above embodiments are only used to help understand the present application. The contents of this specification should not be construed as restricting the present application. At the same time, for those skilled in the art, there will be different forms of changes in the specific embodiments and scope of application according to the present application, and it is not necessary and impossible to exhaust all embodiments here, and the obvious changes or changes derived therefrom are still within the scope of protection of the present application.

1. A display base plate, comprising:
a substrate, wherein a light-emitting diode and a driving circuit are formed on one side of the substrate;
the light-emitting diode, comprising a first semiconductor layer, a light-emitting layer and a second semiconductor layer which are stacked; and
the driving circuit, respectively connected with the first semiconductor layer and the second semiconductor layer, and used for driving the light-emitting diode to emit light.

2. The display base plate according to claim 1, wherein:
the first semiconductor layer is located between the substrate and the light-emitting layer, the first semiconductor layer comprises a first region, an orthographic projection of the first region and an orthographic projection of the light-emitting layer on the substrate are not overlapped, and the orthographic projection of the first region and an orthographic projection of the second semiconductor layer on the substrate are not overlapped.

3. The display base plate according to claim 2, wherein:
the driving circuit comprises a first metal layer, an insulating layer and a second metal layer which are stacked, the first metal layer is arranged close to the substrate, the first metal layer comprises a first adapter portion, and the second metal layer comprises a second adapter portion;
wherein, an orthogonal projection of the first adapter portion and the orthogonal projection of the first region on the substrate are overlapped and lapped with each other, and an orthogonal projection of the second adapter portion and the orthogonal projection of the second semiconductor layer on the substrate are overlapped and lapped with each other.

4. The display base plate according to claim 3, wherein:
a passivation layer is also disposed on one side of the light-emitting diode away from the substrate, and the first metal layer is located on one side of the passivation layer away from the substrate;
wherein, the first adapter portion and the first region are lapped through a first via hole disposed in the passivation layer, and the second adapter portion and the second semiconductor layer are lapped through a second via hole disposed in the passivation layer.

5. The display base plate according to claim 2, wherein the light-emitting diode further comprises:
a first electrode located on a surface of one side of the first region away from the substrate; and
a second electrode located on a surface of one side of the second semiconductor layer away from the substrate.

6. The display base plate according to claim 5, wherein:
the first electrode and the second electrode are made of a transparent conductive material.

7. The display base plate according to claim 2, wherein:
the first semiconductor layer is made of N-GaN, and the second semiconductor layer is made of P-GaN.

8. The display base plate according to claim 2, wherein:
the light-emitting layer is made of a multi-quantum well material.

9. The display base plate according to claim 2, wherein:
a thickness of the first semiconductor layer is greater than that of the second semiconductor layer.

10. The display base plate according to claim 9, wherein:
the thickness of the first semiconductor layer is greater than or equal to 2 μm and less than or equal to 3 μm; and
the thickness of the second semiconductor layer is greater than or equal to 0.5 μm and less than or equal to 1 μm.

11. The display base plate according to claim 10, wherein:
a thickness of the light-emitting layer is greater than or equal to 0.3 μm and less than or equal to 0.7 μm.

12. The display base plate according to claim 2, wherein:
the substrate is a silicon-based substrate.

13. The display base plate according to claim 1, wherein:
the display base plate comprises a plurality of pixels arranged in an array, and each pixel comprises at least one light-emitting diode and the driving circuit connected with each light-emitting diode.

14. A display apparatus, comprising the display base plate according to claim 1.

15. A preparation method of a display base plate, comprising:
providing a substrate;
forming a light-emitting diode on one side of the substrate, wherein the light-emitting diode comprises a first semiconductor layer, a light-emitting layer and a second semiconductor layer which are stacked; and
forming a driving circuit on the side of the substrate, wherein the driving circuit is respectively connected with the first semiconductor layer and the second semiconductor layer, and is used for driving the light-emitting diode to emit light.

16. The display apparatus according to claim 14, wherein, the first semiconductor layer is located between the substrate and the light-emitting layer, the first semiconductor layer comprises a first region, an orthographic projection of the first region and an orthographic projection of the light-emitting layer on the substrate are not overlapped, and the orthographic projection of the first region and an orthographic projection of the second semiconductor layer on the substrate are not overlapped.

17. The display apparatus according to claim 16, wherein:
the driving circuit comprises a first metal layer, an insulating layer and a second metal layer which are stacked, the first metal layer is arranged close to the substrate, the first metal layer comprises a first adapter portion, and the second metal layer comprises a second adapter portion;
wherein, an orthogonal projection of the first adapter portion and the orthogonal projection of the first region on the substrate are overlapped and lapped with each other, and an orthogonal projection of the second adapter portion and the orthogonal projection of the second semiconductor layer on the substrate are overlapped and lapped with each other.

18. The display apparatus according to claim 17, wherein:
a passivation layer is also disposed on one side of the light-emitting diode away from the substrate, and the first metal layer is located on one side of the passivation layer away from the substrate;
wherein, the first adapter portion and the first region are lapped through a first via hole disposed in the passivation layer, and the second adapter portion and the second semiconductor layer are lapped through a second via hole disposed in the passivation layer.

19. The display apparatus according to claim 16, wherein the light-emitting diode further comprises:
a first electrode located on a surface of one side of the first region away from the substrate; and
a second electrode located on a surface of one side of the second semiconductor layer away from the substrate.

20. The display apparatus according to claim 19, wherein:
the first electrode and the second electrode are made of a transparent conductive material.
